(19) United States
(12) Patent Application Publication
(10) Pub. No.: US 2008/0023776 A1
(43) Pub. Date: Jan. 31, 2008

(54) Metal oxide semiconductor device with improved threshold voltage and drain junction breakdown voltage and method for fabricating same

(75) Inventor: Allan Laser, San Jose, CA (US)

Correspondence Address: DORSEY & WHITNEY LLP, 555 CALIFORNIA STREET, SUITE 1000, SUITE 1000, SAN FRANCISCO, CA, 94104, US

(73) Assignee: MICREL, INCORPORATED

(21) Appl. No.: 11/493,294

(22) Filed: Jul. 25, 2006

(51) Int. Cl. H01L 29/76; H01L 21/336

(52) U.S. Cl. 257/408; 438/306; 257/E29.266

(57) ABSTRACT

A metal oxide semiconductor device having a substrate layer of a semiconductor material and a gate, a source and, a drain formed over the substrate layer is provided. The substrate is doped with a deep n-type lightly doped drain implant that simmultaneously lowers the threshold voltage and increases the drain junction breakdown voltage of the device. A method of fabricating a metal oxide semiconductor device is also divided.

### FIELD OF THE INVENTION

The present invention relates generally to semiconductor devices, and more particularly to metal oxide semiconductor devices.

### BACKGROUND INFORMATION

Complementary metal-oxide semiconductor (“CMOS”) devices typically use both n-type metal oxide semiconductor (“NMOS”) and p-type metal oxide semiconductor (“PMOS”) circuits to reduce their overall power consumption. Since only one of the circuit types is on at any given time, CMOS devices require less power than devices using just one type of circuit, which makes them particularly attractive for use in portable computers, cell phones and personal digital assistants and other battery-powered devices.

As CMOS devices become more prevalent across a wide range of industrial and commercial applications, there is an increased need to make them suitable for both the low and high voltage operation required in these applications. Thicker gate oxides and special drain engineering are used to address the requirements for high voltage operation of CMOS devices. The use of thicker gate oxides result in undesirable higher threshold voltages. The high voltages allowed on the drain terminal require custom drain junction implants to be used to increase junction breakdown levels and minimize hot carrier effects, such as Lightly Doped Drain implants (“LDD”), N-Type Lightly Doped Drain (“NLDD”) implants, or P-type Lightly Doped Drain (“PLDD”) implants.

These implants, however, cannot typically penetrate the gate region of the devices, thereby reducing their ability to lower the threshold voltage to desired levels. As a result, an additional threshold voltage adjust implant may be required. This threshold voltage adjust implant is not ideal for both low and high voltage operation because a different gate oxide thickness is used for each. Separate masking operations may be required to adjust the low voltage threshold independent of the high voltage threshold.

There is, therefore, a need to use an implant in a CMOS device that is capable of simultaneously reducing the threshold voltage and hot carrier formation in the device, without the need for an additional threshold voltage adjust implant.

### SUMMARY OF THE INVENTION

A metal oxide semiconductor device having a substrate layer of a semiconductor material and a gate, a source and a drain formed over the substrate layer is provided. The substrate is doped with a deep n-type lightly doped drain implant that simultaneously lowers the threshold voltage and increases the drain junction breakdown voltage of the device.

### BRIEF DESCRIPTION OF THE DRAWINGS

The accompanying drawings, which are somewhat schematic in some instances and are incorporated in and form a part of this specification, illustrate several embodiments of the invention and, together with the description, serve to explain the principles of the invention.

FIG. 1 shows a cross-section of an N-type metal oxide semiconductor device of the present invention after implantation of the deep n-type lightly doped drain implant into the gate, drain and source regions;

FIG. 2 shows a cross-section of the N-type metal oxide semiconductor device of FIG. 1 prior to the implantation of the deep n-type lightly doped drain implant;

FIG. 3 shows a cross-section of the N-type metal oxide semiconductor device of FIG. 1 with the application of a mask photoresist prior to the implantation of the deep n-type lightly doped drain implant;

FIG. 4 shows a cross-section of the N-type metal oxide semiconductor device of FIG. 1 with the deep n-type lightly doped drain implant being applied into the gate, source, and drain regions;

FIG. 5 is a flowchart of representative steps taken in the method of the present invention to apply a deep n-type lightly doped drain implant into a complementary metal oxide semiconductor device;

FIG. 6 is a graph showing the threshold voltage versus the energy of the deep n-type lightly doped drain implant used in the device of FIG. I for different phosphorous doses; and

FIG. 7 is a graph showing the junction breakdown versus the energy of the deep n-type lightly doped drain implant used in the device of FIG. 1 for different phosphorous doses.

### DETAILED DESCRIPTION OF EMBODIMENTS OF THE INVENTION

In one embodiment of the present invention, a deep n-type lightly doped drain (“DNLDD”) implant is used over the entire gate and drain regions of a CMOS device to increase the drain junction breakdown voltage by placing a lighter and deeper implant in the drain region. The DNLDD implant additionally lowers the threshold voltage by penetrating the gate and becoming a part of the surface channel doping.

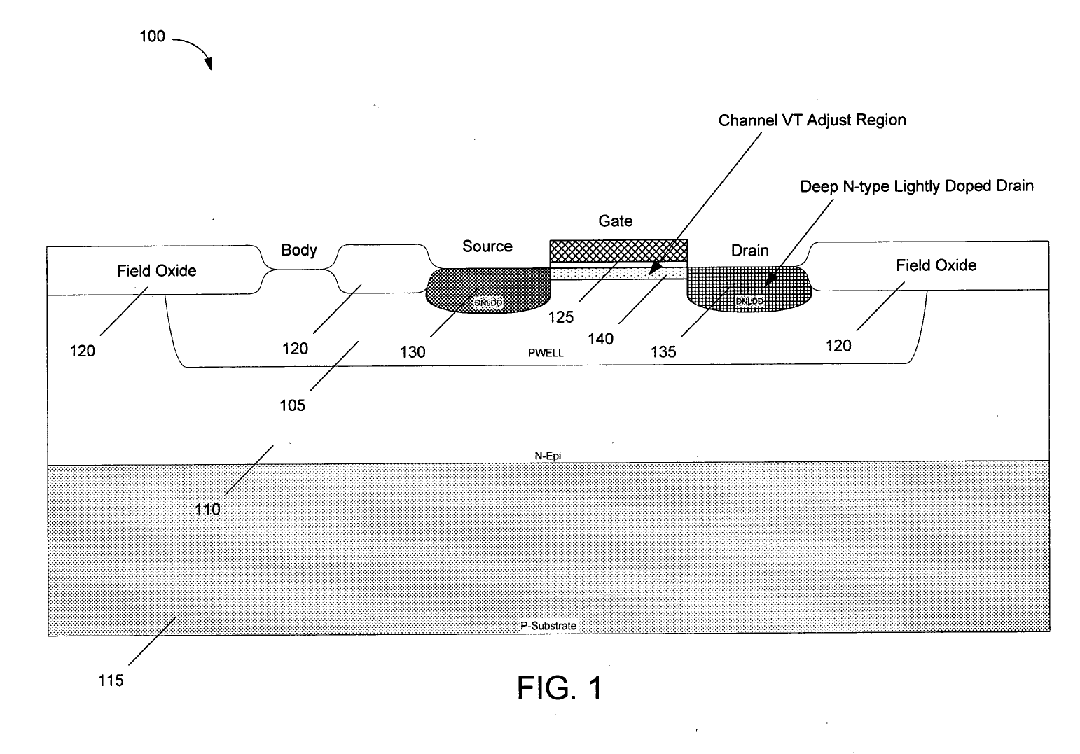

A cross-section of a typical CMOS device after implantation of the deep n-type lightly doped drain implant into the gate, drain and source regions is shown in FIG. 1. CMOS device 100 is an NMOS transistor that is located in a deep, lightly doped p-well 105 that is defined over an n-doped epitaxial (“n-epi”) silicon layer 110 and p-substrate layer 115. Field oxide layer 120 is used to isolate transistors that may be built over layers 110 and 115, i.e., to isolate different transistors from each other.

NMOS transistor 100 is shown with gate 125, source 130, and drain 135. Applying a phosphorous DNLDD implant over gate 125, source 130, and drain 135 results in deeper source and drain regions. Also, because the DNLDD implant is of sufficient energy to penetrate polysilicon gate 125, a portion of it reaches the surface channel of gate 125 and creates channel adjust region 140 that results in lower threshold voltages. The drain junction breakdown voltages are also higher because of the implantation of the deep and high energy DNLDD implant.

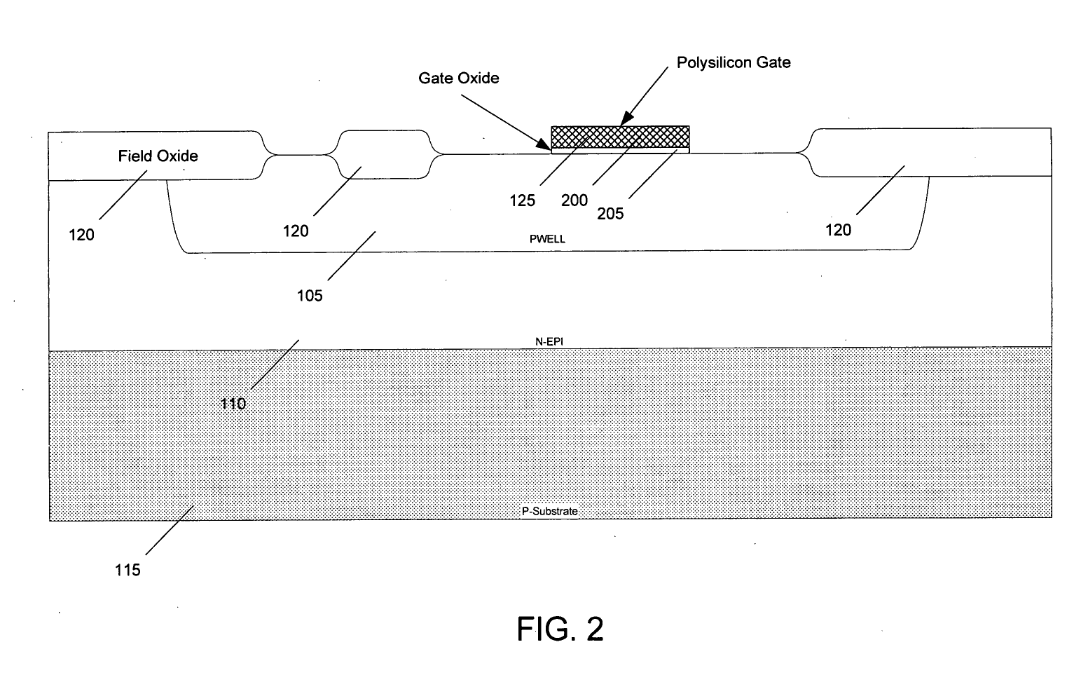

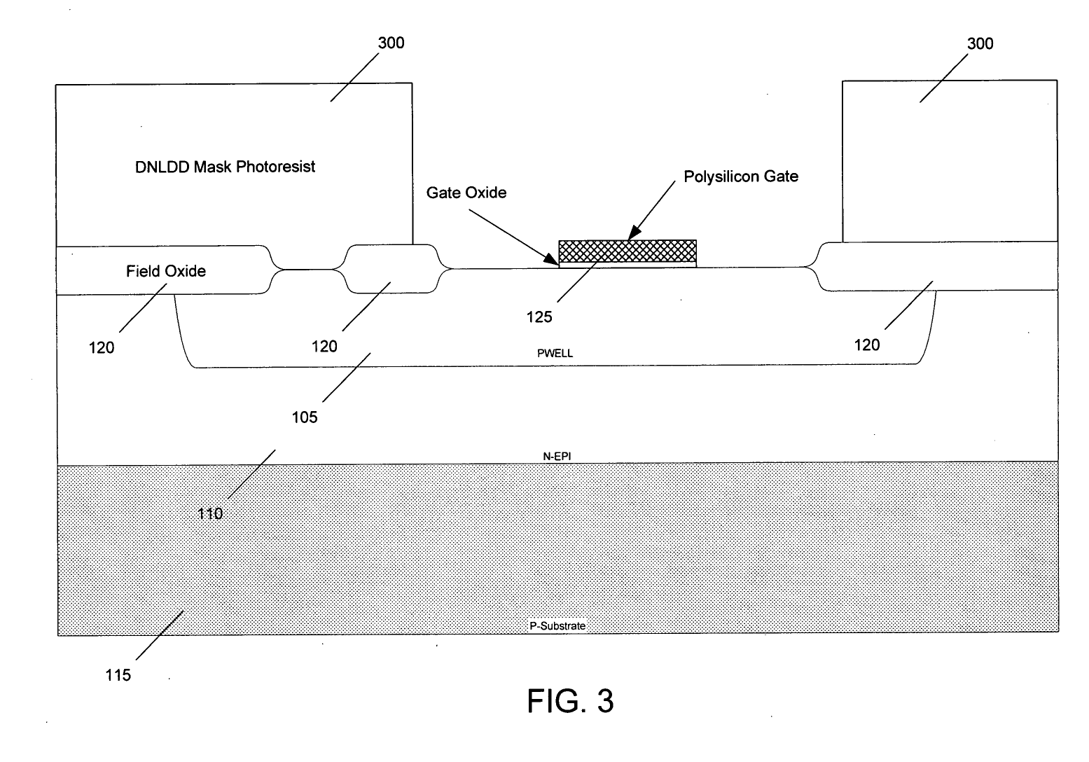

The process flow for implanting a DNLDD implant into a CMOS device, such as NMOS transistor 100, in accordance with the present invention is described with reference to FIGS. 2-4. A cross-section of NMOS transistor 100 prior to the implantation of the deep n-type lightly doped drain implant is shown in FIG. 2. At this point in the process, the foundations for building NMOS transistor 100 in p-well 105 over n-epi layer 110 and p-substrate layer 115 are in place. Field oxide layer 120 is also shown for isolating NMOS transistor 100 from other transistors that may be built over layers 110 and 115. At this stage, gate 125 is formed with gate oxide layer 205 and amorphous polysilicon gate 200. In this representative embodiment, gate oxide layer 205 measures 350 Angstroms and polysilicon gate 200 measures 3000 Angstroms. 019 The next process step for creating NMOS transistor 100 with a DNLDD implanted therein to lower its threshold voltage and increase its drain junction breakdown voltage is shown in FIG. 3 with the application of DNLDD mask photoresist 300. In a conventional CMOS process flow, during drain and source formation, the polysilicon gate is already in place and a photomasking operation is used to define the openings intended to receive an implant.

DNLDD mask photoresist 300 opens up both source region 130 and drain region 135 (shown in FIG. 1). However, if a different implant is desired for one region, i.e., if one implant is desired for the drain region and another implant is desired for the source region, DNLDD mask photoresist 300 may be applied so as to block the source region of the device, for example, and leave only the gate and drain regions of the device open.

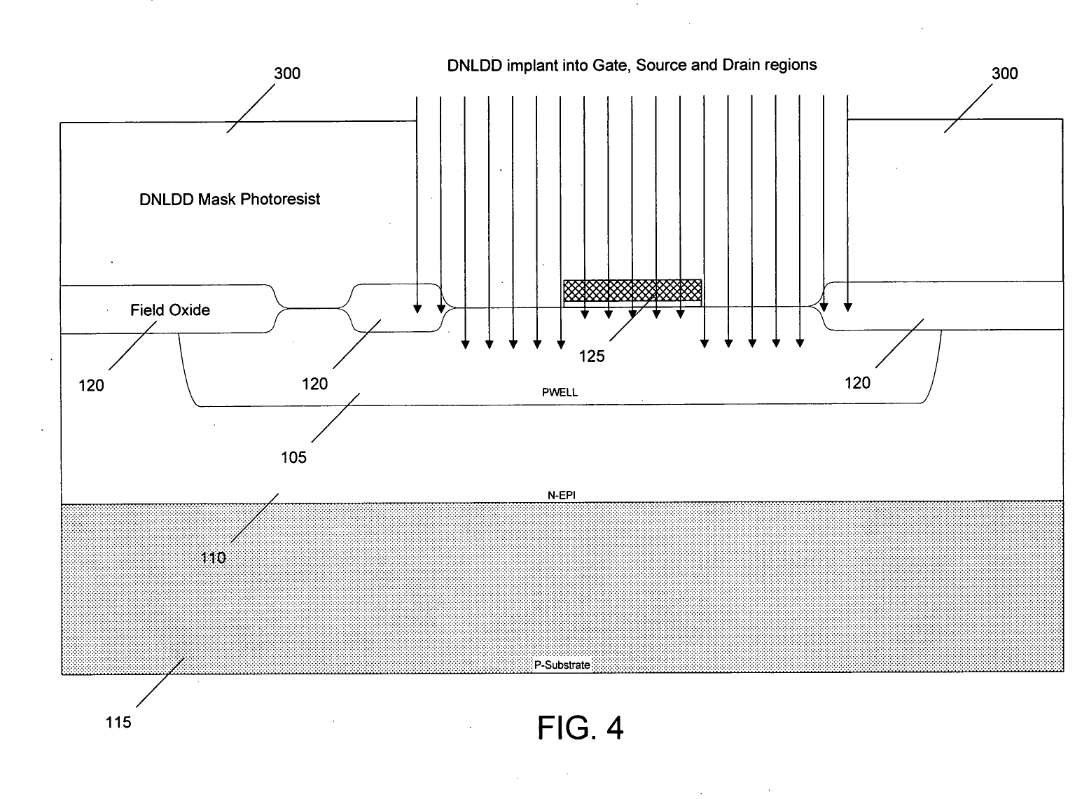

The next process step is shown in FIG. 4 with the DNLDD implant being applied to the gate, source, and drain regions of NMOS transistor 100. The arrows shown in FIG. 4 illustrate the relative depth that the DNLDD implant reaches. Source region 130 and drain region 135 are completely open to the DNLDD implant and therefore receive the deepest implant. Polysilicon gate region 200 in gate 125 blocks some of the ions and minimizes the depth that they penetrate into silicon layer 105 below gate 125. Mask photoresist 300 and field oxide regions 120 effectively block all of the DNLDD implant from reaching silicon layers 105, 110, and 115 below those regions.

The result of this DNLDD implantation process step is shown in FIG. 1, as described above, with source region 130 and drain region 135 being formed with a greater depth and gate region 125 having channel adjust region 140 below polysilicon gate region 200 in gate 125. The use of the DNLDD implant simultaneously allows for higher drain junction breakdown voltages and reduces the threshold voltage of NMOS devices.

It is understood that CMOS device 100 is shown as a NMOS transistor for illustration purposes only. A PMOS transistor or a combination of NMOS and PMOS transistors may be formed with the use of DNLDD and deep p-type lightly doped drain (“DPLDD”) implants without deviating from the principles and embodiments of the present invention. It should also be understood by one skilled in the art that the DNLDD implant may be applied to the gate and drain regions only and another implant may be used in the source region.

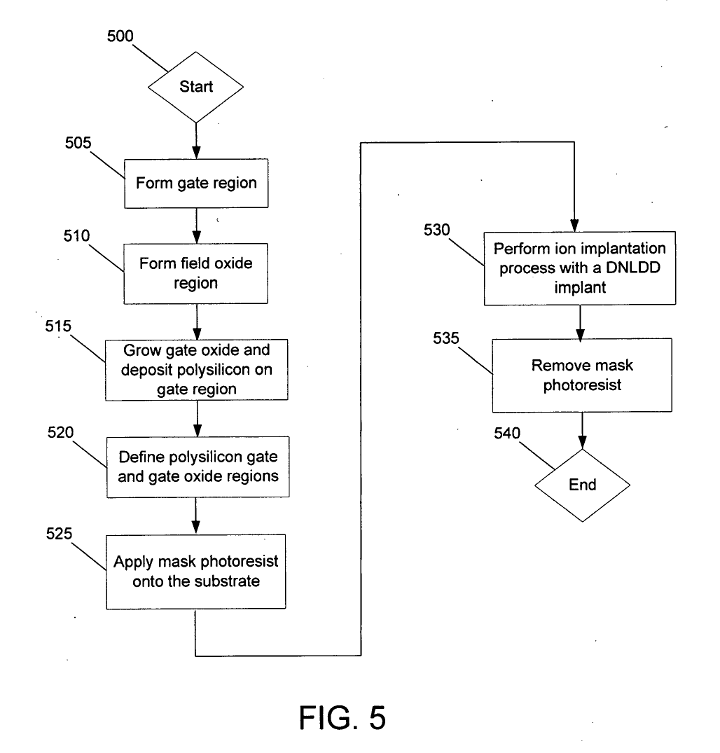

A flowchart illustrating the CMOS process steps of FIGS. 2-4 taken for applying the DNLDD implant in the formation of a CMOS device is shown in FIG. 5. At step 505, gate region 125 is defined on top of silicon layers 105, 110, and 115. Field oxide regions 120 are formed at step 510. The next step (515) includes the growth of gate oxide and deposition of polysilicon used to define gate region 125. At step 520, the polysilicon gate 200 and gate oxide 205 regions are defined using a combination of photolithography and etch processes.

The DNLDD implantation process starts with the application of a mask photoresist at step 525. The DNLDD implant is applied to gate region 125, source region 130 and drain region 135 at step 530. The mask photoresist is removed at step 535 to form a CMOS device with the DNLDD implant, such as NMOS transistor 100 shown in FIG. 1.

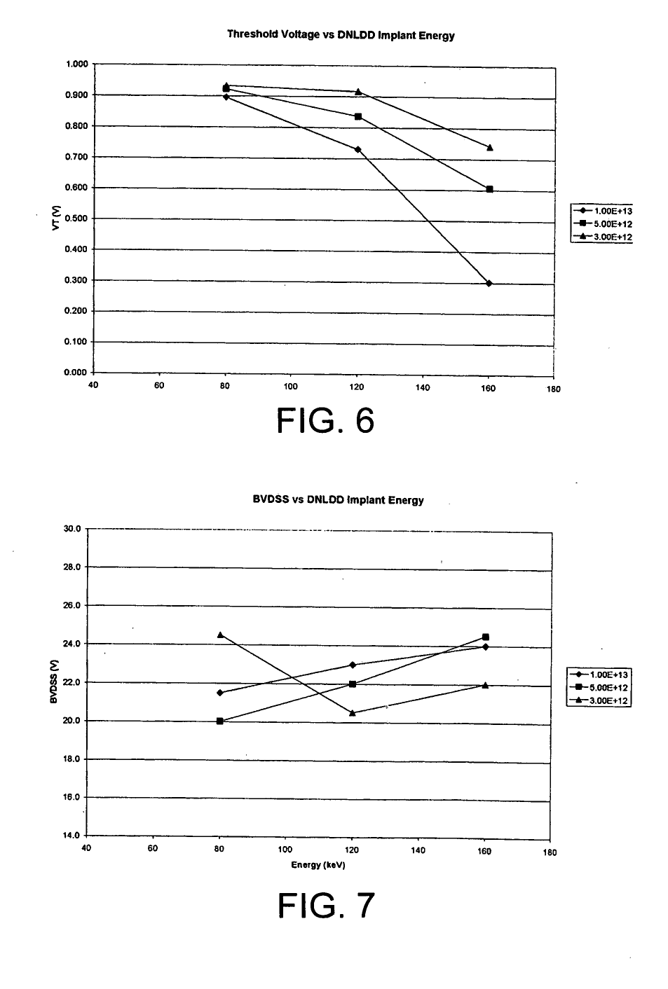

The improvements obtained with the application of the DNLDD implant to form NMOS transistor 100 are illustrated in FIGS. 6-7. The DNLDD implant energy level is at least 80 kilo-electronvolts. FIG. 6 is a graph showing the threshold voltage versus the energy of the DNLDD implant for different phosphorous dosages. For a desired threshold voltage of 0.75 Volts, a DNLDD implant of 120 kilo-electronvolts may be used. The higher the energy of the implant, the lower the threshold voltage achieved in the CMOS device. The threshold voltage achieved is less than 1 Volt.

FIG. 7 is a graph showing the junction breakdown voltages versus the energy of the DNLDD implant for different phosphorous dosages. Increasing the energy of the DNLDD implant increases the drain junction breakdown voltage in the CMOS device and reduces hot carrier formation in the drain region due to the lighter and deeper dopant profile in the region. The junction breakdown voltage is at least 20 Volts.

Advantageously, using a DNLDD implant to form a CMOS device in accordance with the present invention has the effect of simultaneously lowering the threshold and increasing the junction breakdown voltage in the device.

The foregoing descriptions of specific embodiments and best mode of the present invention have been presented for purposes of illustration and description only. They are not intended to be exhaustive or to limit the invention to the precise forms disclosed. Specific features of the invention are shown in some drawings and not in others, for purposes of convenience only, and any feature may be combined with other features in accordance with the invention. Steps of the described processes may be reordered or combined, and other steps may be included. The embodiments were chosen and described in order to best explain the principles of the invention and its practical application, to thereby enable others skilled in the art to best utilize the invention and various embodiments with various modifications as are suited to the particular use contemplated. Further variations of the invention will be apparent to one skilled in the art in light of this disclosure and such variations are intended to fall within the scope of the appended claims and their equivalents.

What is claimed is:

1. A metal oxide semiconductor device comprising a substrate layer of a semiconductor material, a gate, a source, and a drain formed over the substrate layer, the gate and the drain being doped with a deep N-type lightly doped drain implant for lowering the threshold voltage and increasing the junction breakdown voltage of the device.

2. The semiconductor device of claim 1, wherein the substrate layer, the gate, the source, and the drain form a transistor.

3. The semiconductor device of claim 1, wherein the transistor is formed in a P-WELL layer overlying either an EPI layer, a substrate layer, or a combination of both.

4. The semiconductor device of claim 1, wherein the transistor is formed in an N-WELL layer overlying either an EPI layer, a substrate layer, or a combination of both.

5. The semiconductor device of claim 1, wherein the gate includes a gate oxide layer and a polysilicon layer.

6. The semiconductor device of claim 1, wherein the implant includes a phosphorous implant.

7. The semiconductor device of claim 1, wherein the implant includes a boron implant.

8. The semiconductor device of claim 1, wherein the drain and source are doped with the N-type lightly doped drain implant.

9. The semiconductor device of claim 1, wherein the lightly doped drain implant has an energy level of at least 80 kilo-electronvolts.

10. The semiconductor device of claim 1, wherein the threshold voltage is less than 1 Volt.

11. The semiconductor device of claim 1, wherein the junction breakdown voltage is at least 20 Volts.

12. A method for fabricating a metal oxide semiconductor device on a substrate layer of a semiconductor material, comprising forming a gate, a source and a drain over the substrate layer, applying a mask photoresist on the substrate layer, and performing an ion implantation process using a deep N-type lightly doped drain implant that penetrates the gate and the drain for lowering the threshold voltage and increasing the junction breakdown voltage of the device.

13. The method of claim 12, further comprising removing the mask photoresist after the ion implantation process.

14. The method of claim 12, further comprising forming a field oxide region on the substrate to isolate the device from another device formed on the substrate.

15. The method of claim 14, wherein the mask photoresist and the field oxide region block the implant from reaching into the substrate.

16. The method of claim 12, wherein the performing step includes using the deep N-type lightly doped drain implant to penetrate the gate of the device.

17. The method of claim 16, wherein the performing step includes penetrating the implant deeper into the source and drain regions than in the gate region.
